(19) United States
(12) Patent Application Publication
(10) Pub. No.: US 2015/0333128 A1
(43) Pub. Date: Nov. 19, 2015

(54) N-TYPE III-V SEMICONDUCTOR STRUCTURES HAVING ULTRA-SHALLOW JUNCTIONS AND METHODS OF FORMING SAME

(71) Applicant: Sematech, Inc., Albany, NY (US)

(72) Inventors: Rinus LEE, Albany, NY (US); Wei-Yip LOH, Loudonville, NY (US); Robert TIECKELMANN, Clifton Park, NY (US)

(73) Assignee: SEMATECH, INC., Albany, NY (US)

(21) Appl. No.: 14/277,887

(22) Filed: May 15, 2014

(51) Int. Cl. H01L 29/207; H01L 29/66; H01L 21/324; H01L 29/78

(52) U.S. Cl. CPC H01L 29/207; H01L 29/78; H01L 29/66477; H01L 21/324

(57) ABSTRACT

Provided are methods of fabricating a semiconductor structure. The methods include providing a III-V semiconductor substrate selected from InGaAs and InAs, introducing an n-type dopant selected from S, Se, and Te directly onto a surface of the III-V semiconductor substrate, introducing a co-dopant selected from N and P directly onto a surface of the III-V semiconductor substrate, and diffusing the n-type and co-dopant into the III-V semiconductor substrate, thereby forming an n-doped III-V semiconductor substrate containing the n-type dopant and the co-dopant. The methods produce inventive semiconductor structures, and devices that include the semiconductor structure.

### FIELD OF THE INVENTION

The present invention generally relates to semiconductor devices and device fabrication. Specifically, the invention relates to methods of forming semiconductor structures using a co-doping process, and to the resultant semiconductor structures.

### BACKGROUND OF THE INVENTION

The use of III-V compound semiconductor substrates has been widely explored as a means to improve integrated circuit performance. As described by Moore's law, the semiconductor industry drives down pattern dimensions in order to reduce transistor size and enhance processor speed at a rapid pace. Coexisting with Moore's law and further influencing the continued shrinking of transistors is the International Technology Roadmap for Semiconductors (ITRS).

The ITRS is a reference guide that projects the semiconductor industry's future technology requirements. Since today's semiconductor research and development is geared to provide semiconductor devices that meet future needs, the ITRS is viewed as an important guiding reference within the semiconductor industry.

However, by virtue of its ever-evolving nature, the semiconductor industry has yet to achieve technology parameters that the ITRS sets forth as future industry requirements. One such parameter is the shallow junction (X_{J}) requirement.

As devices scale smaller, it is imperative to achieve reduced depth of doped source/drain regions. However, industry processes of record have proved inadequate at achieving satisfactory semiconductor structures having ultra-shallow junctions.

Thus, a need exists for improved semiconductor structures having ultra-shallow junctions, and for methods of forming the same.

While certain aspects of conventional technologies have been discussed to facilitate disclosure of the invention, Applicants in no way disclaim these technical aspects, and it is contemplated that the claimed invention may encompass one or more of the conventional technical aspects discussed herein.

In this specification, where a document, act or item of knowledge is referred to or discussed, this reference or discussion is not an admission that the document, act or item of knowledge or any combination thereof was, at the priority date, publicly available, known to the public, part of common general knowledge, or otherwise constitutes prior art under the applicable statutory provisions; or is known to be relevant to an attempt to solve any problem with which this specification is concerned.

### SUMMARY OF THE INVENTION

Briefly, the present invention satisfies the need for improved semiconductor structures having ultra-shallow junctions, and for methods of forming the same. The present invention may address one or more of the problems and deficiencies of the art discussed above. However, it is contemplated that the invention may prove useful in addressing other problems and deficiencies in a number of technical areas. Therefore, the claimed invention should not necessarily be construed as limited to addressing any of the particular problems or deficiencies discussed herein.

Certain embodiments of the presently-disclosed methods of forming semiconductor structures and resultant semiconductor structures have several features, no single one of which is solely responsible for their desirable attributes. Without limiting the scope of the inventive method and products as defined by the claims that follow, their more prominent features will now be discussed briefly. After considering this discussion, and particularly after reading the section of this specification entitled “Detailed Description of the Invention,” one will understand how the features of the various embodiments disclosed herein provide a number of advantages over the current state of the art.

For example, a key issue involved in semiconductor device scaling relates to reducing the depth of doped source/drain regions while maintaining low resistance. Industry standard processes of record result in significant dopant diffusion and defect formation, which causes deeper junctions and increased sheet resistance. Embodiments of the present invention address these and other deficiencies in the art.

These and other features and advantages of this invention will become apparent from the following detailed description of the various aspects of the invention taken in conjunction with the appended claims and the accompanying figure.

### BRIEF DESCRIPTION OF THE DRAWINGS

FIG. 1 is a graph showing n-type dopant concentration as a function of substrate depth for an embodiment of the invention and a counterexample.

### DETAILED DESCRIPTION OF THE INVENTION

Aspects of the present invention and certain features, advantages, and details thereof, are explained more fully below with reference to the non-limiting embodiments illustrated in the accompanying drawings. Descriptions of well-known materials, fabrication tools, processing techniques, etc., are omitted so as to not unnecessarily obscure the invention in detail. It should be understood, however, that the detailed description and the specific examples, while indicating embodiments of the invention, are given by way of illustration only, and are not by way of limitation. Various substitutions, modifications, additions and/or arrangements within the spirit and/or scope of the underlying inventive concepts will be apparent to those skilled in the art from this disclosure.

In one aspect, the invention provides a method of fabricating a semiconductor structure. The method includes:
providing a III-V semiconductor substrate selected from InGaAs and InAs;
introducing an n-type dopant directly onto a surface of the III-V semiconductor substrate, wherein said n-type dopant is selected from sulfur (S), selenium (Se), and tellurium (Te);
introducing a co-dopant directly onto a surface of the III-V semiconductor substrate, wherein said co-dopant is selected from nitrogen (N) and phosphorus (P);
diffusing the n-type dopant into the III-V semiconductor substrate; and
diffusing the co-dopant into the III-V semiconductor substrate;
   thereby forming an n-doped III-V semiconductor substrate containing the n-type dopant and the co-dopant.

III-V semiconductor materials are those comprising atoms of Group III elements and atoms of Group V elements. The present invention utilizes a III-V semiconductor material selected from InGaAs and InAs. The InAs/GaAs ternary alloy (InGaAs) can be characterized as InₓGa₁₋ₓAs where x is the proportion of InAs and ₁₋ₓ is the proportion of GaAs. InGaAs with 53% InAs is often called “standard InGaAs.” The present invention encompasses, as a III-V, InGaAs of all concentrations.

An n-type semiconductor material (e.g., n-doped III-V semiconductor substrate) is a material which has been doped with dopant atoms capable of providing extra conduction electrons to the host material, thereby creating an excess of negative (n-type) electron charge carriers.

The present invention utilizes co-doping of an n-type dopant (i.e., one or more dopants) selected from sulfur (S), selenium (Se), and tellurium (Te), together with a co-dopant selected from nitrogen (N) and phosphorus (P), to dope a III-V semiconductor substrate, thereby forming an n-doped III-V semiconductor substrate containing the n-type dopant and the co-dopant.

It has been found that in the inventive co-doping process, the co-dopant (phosphorus and/or nitrogen) acts as a diffusion inhibitor and limits the diffusion of the n-type dopant in the III-V semiconductor substrate, thereby enabling the formation of ultra-shallow junctions.

The mechanism behind the inventive diffusion inhibiting co-doping process relates to the co-dopant's ability to inhibit n-type dopant diffusion into the III-V semiconductor substrate. The n-type dopant used in the invention (S, Se, and/or Te) has six electrons, and, upon doping, will occupy group V atom sites in a III-V semiconductor (e.g., As sites in InGaAs). By replacing a group V element in the lattice (which would have 5 electrons) with the n-type dopant, which has six electrons, the n-type dopant provides a surplus electron, and acts as a donor in the III-V lattice, thereby forming an n-type III-V semiconductor material.

N-type dopants diffuse from III-V materials via a kickout mechanism, which is interstitial-based. Annealing processes are known to cause significant dopant diffusion, which results in deeper junctions. However, the inventive method inhibits diffusion of the n-type dopant because the co-dopant (N and/or P) occupies unoccupied group V sites in the III-V lattice, and also supersaturates group V interstitial sites, thereby eliminating interstitial group V sites for the n-type dopant to diffuse out through. Thus, the inventive method inhibits n-type dopants from diffusing deeper into the III-V semiconductor by eliminating some or all of the diffusion pathways (group V sites and/or interstitial sites).

Co-doping has been described in the prior art, but prior art co-doping relates to processes and purposes that differ from those described herein. For example, Hyuga et al., Activation Efficiency Improvements in Si-Implanted GaAs by P Co-Implantation, Appl. Phys. Lett. 50, 1592 (1987) discloses doping amphoteric silicon (Si) with N and P, but this was done to prevent the Si dopant from forming p-type III-V by occupying an As site in GaAs. Unlike the presently-disclosed invention, which uses different dopants, Hyuga et al. require use of Si because it is an amphoteric dopant. Thus, when incorporated into the GaAs, Si acts either as a donor (n-type, when it occupies Ga lattice sites) or as an acceptor (p-type, when it occupies As lattice sites).

To explain in greater detail, a Si atom has four electrons disposable for binding. If it replaces a Ga atom that had only three electrons, the As partner does not have to supply an electron anymore to make up for its “deficient” partner Ga, and the surplus electron from its As partner will only be weakly bound—it will easily escape into the conduction band and become a free electron (hence forming n-type III-V semiconductor).

On the other hand, if an As atom that has five electrons is replaced by a Si atom, which has only 4 electrons, the new twosome is now short by one electron. It therefore will fill its hole by an electron from the valence band—Si now acts an acceptor (hence forming p-type III-V semiconductor).

Hyuga et al. implant group V N or P to occupy the As vacancies, thereby forcing the amphoteric Si dopant to occupy Ga sites, hence forming n-type III-V semiconductor. The problems faced by Hyuga et al. thus are specific and inherent to the amphoteric properties of their Si dopant. The field of endeavor is to prevent Si from occupying the As site by filling the As site, thereby forcing the Si to occupy the Ga site and thus enhance activation efficiency. Unlike Hyuga et al., which is directed to preventing the amphoteric Si dopant from forming p-type GaAs, the present co-doping method prevents the diffusion of non-amphoteric n-type dopants (which cannot form p-type III-V) by saturating group V lattice sites.

Returning to the inventive method of fabricating a semiconductor structure, as indicated above, the method includes introducing directly onto the III-V semiconductor substrate surface both an n-type dopant selected from S, Se, and Te, and a co-dopant (diffusion inhibitor) selected from N and P. The inventive method encompasses introducing (and doping) one or more of each of the n-type dopant (i.e., one or more of S, Se, and Te) and the co-dopant (i.e., one or both of N and P).

The inventive method and semiconductor structures find use in, for example, doping III-V semiconductors with minimal dopant diffusion, forming ultra-thin doping layers in III-V semiconductor materials, and ultra-shallow junction formation in devices that require doped junctions (e.g., III-V FETs, III-V nanowire FETs, 2D FETs, etc.).

In some embodiments, the inventive method includes doping the III-V semiconductor substrate with any other desired dopants in addition to the n-type dopant(s) and co-dopant(s).

In some embodiments of the inventive method, the introducing the n-type dopant into the III-V semiconductor substrate and the introducing the co-dopant into the III-V semiconductor substrate are performed simultaneously. In other embodiments, the introducing steps are performed sequentially (e.g., n-type dopant is introduced first and co-dopant second, or co-dopant is introduced first, and n-type dopant second).

The introducing an n-type dopant directly onto a surface of the III-V semiconductor substrate, and the introducing a co-dopant directly onto a surface of the III-V semiconductor substrate, may be carried out in any manner that introduces the dopants to the semiconductor surface. In some non-limiting embodiments, the introducing steps are accomplished by traditional ion implantation, molecular beam epitaxy (MBE), metal organic chemical vapor deposition (MOCVD), monolayer deposition (MLD), plasma deposition, or vapor phase deposition.

In some embodiments, the introducing an n-type dopant directly onto the surface of the III-V semiconductor substrate, and the introducing a co-dopant directly onto the surface of the III-V semiconductor substrate are accomplished by an MLD process.

MLD utilizes the crystalline nature of semiconductors and its self-limiting surface reaction properties to form highly uniform, self-assembled, covalently bonded dopant-containing monolayers followed by, e.g., a subsequent annealing step for the incorporation and diffusion of dopants. The monolayer formation reaction is self-limiting, thereby, resulting in the deterministic coverage of dopant atoms on the III-V surface. MLD differs from other conventional doping techniques such as spin-on-dopants (SODs) and gas phase doping techniques in the way of dopant dose control. Such control in MLD is much more precise due to the self-limiting formation of covalently attached dopants on the surface while the SODs just rely on the thickness control of the spin-on oxide and the gas phase technique depends on the control of dopant gas flow rate; therefore, the excellent dose control in MLD can attribute to desirable fine tuning of the resulting dopant profile.

In some embodiments of the invention, the introducing an n-type dopant directly onto a surface of the III-V semiconductor substrate, and the introducing a co-dopant directly onto a surface of the III-V semiconductor substrate are accomplished by an MLD process that comprises contacting the III-V semiconductor surface with a solution comprising the n-type dopant and the co-dopant, thereby forming a layer comprising the n-type dopant and the co-dopant directly on the III-V semiconductor surface. Thus, the solution comprises one or more of S, Se, and Te, and one or more of N and P.

In some embodiments, the introducing an n-type dopant directly onto a surface of the III-V semiconductor substrate, and the introducing a co-dopant directly onto a surface of the III-V semiconductor substrate, are accomplished by an MLD process that comprises contacting the III-V semiconductor surface with a solution comprising a compound that comprises phosphorus and sulfur.

In some embodiments, the solution used for the MLD process comprises an inorganic and/or organic phosphorus sulfide compound. In some embodiments, the solution comprises tetraphosphorus decasulfide.

In some embodiments, the solution used for the MLD process comprises an inorganic compound selected from tetraphosphorus trisulfide (P₄S₃), tetraphosphorus pentasulfide (P₄S₅), tetraphosphorus hexasulfide (P₄S₆), tetraphosphorus heptasulfide (P₄S₇), tetraphosphorus nonasulfide (P₄S₉), and tetraphosphorus decasulfide (P₄S₁₀) (also known as phosphorus pentasulfide, P₂S₅).

In some embodiments, the solution used for the MLD process comprises a compound that is a trialkylphosphine sulfide (e.g., triethylphosphine sulfide), a triarylphosphine sulfide (e.g., triphenylphosphine sulfide), a monothiophosphate (e.g., diazinon, parathion, malathion), a dithiophosphates (organic or inorganic), a trithiophosphate (e.g., inorganic trithiophosphate, PS₄³⁻), a triakyl tetrathiophosphate, a triaryl tetrathiophosphates, a thiophosphoric monoamide, a thiophosphoric diamide, a thiophosphoric triamide, or a phosphorus sulfide dimer (e.g., Lawesson's Reagent).

In some embodiments, the solution used for the MLD process comprises a compound selected from a cycloalkene- or aryl-thionophosphine sulfide.

In some embodiments, the solution used for the MLD process comprises an arylphosphonothioic dichloride.

In some embodiments, the solution used for the MLD process comprises a compound selected from cyclohexenylthionophosphine sulfide, p-anisylthionophosphine sulfide, p-phenetylthionophosphine sulfide, 2-naphthylthionophosphine sulfide, and phenylthionophosphine sulfide.

Additional compounds that may be used in the solution for the MLD process are described, for example, in Lecher et al., The Phosphonation of Aromatic Compounds with Phosphorus Pentasulfide, JACS, Vol 78, page 5018-5022 (1956).

The diffusing the n-type dopant into the III-V semiconductor substrate and the diffusing the co-dopant into the III-V semiconductor substrate achieve a doped semiconductor substrate.

Persons having ordinary skill in the art will appreciate that in various embodiments, it is desirable to deposit an oxide layer (e.g., silicon oxide) on the portion of the III-V semiconductor substrate surface being doped prior to the diffusing step. In some embodiments, the oxide layer is 5-50 nm thick.

In some embodiments of the inventive method, the diffusing the n-type dopant into the III-V semiconductor substrate and the diffusing the co-dopant into the III-V semiconductor substrate are performed simultaneously, for example, via an anneal process. In other embodiments, the co-dopant is diffused into the III-V semiconductor substrate prior to diffusion of the n-type dopant. For example, the co-dopant may be introduced into the III-V semiconductor substrate prior to the introduction and diffusion of the n-type dopant.

Annealing is known in the art. Where diffusion is achieved via annealing, inventive embodiments encompass any desired annealing capable of diffusing the n-type dopant and co-dopant into the semiconductor substrate, including both convention and non-conventional annealing, such as flash anneal, spike anneal, microwave anneal, laser anneal, or soak anneal. Annealing may be carried out at any desirable diffusion-achieving temperature Annealing is commonly carried out, e.g., in an inert atmosphere such as argon, at temperatures from 300° C. to 1100° C. In certain embodiments the substrate may be annealed at a temperature between 400° C. and 1000° C. for a period of 1 second to 60 minutes (including any and all ranges and subranges therein, e.g., 1-60 seconds). The expression “from 300° C. to 1100° C.” means that the process is carried out either by maintaining any temperature between 300° C. and 1100° C. or by varying the temperature within that range. In some embodiments, the annealing is carried out at a temperature of 450° C. to 800° C., for example, 450, 475, 500, 525, 550, 575, 600, 625, 650, 675, 700, 725, 750, 775, or 800° C., including any and all ranges and subranges therein (e.g., 600° C. to 750° C.).

In some embodiments, the diffusing the n-type dopant into the III-V semiconductor substrate and the diffusing the co-dopant into the III-V semiconductor substrate result in a doped III-V semiconductor substrate (i.e., doped with at least the n-type dopant and co-dopant), where the doped portion of the semiconductor substrate has an n-type dopant concentration that is greater than or equal to 5×10¹⁸ atoms/cm³ over a depth of less than or equal to 12 nm from the surface of the III-V semiconductor substrate, and is less than 5×10¹⁸ atoms/cm³ beyond 12 nm from the surface of the semiconductor substrate. For example, in some embodiments, the n-type dopant concentration is greater than or equal to 5×10¹⁸ atoms/cm³ over a depth of 12 nm, 11 nm, 10 nm, 9 nm, 8 nm, 7 nm, 6 nm, 5 nm, or 4 nm, and the n-dopant concentration is less than 5×10¹⁸ atoms/cm³ beyond a depth of 12 nm, 11 nm, 10 nm, 9 nm, 8 nm, 7 nm, 6 nm, 5 nm, or 4 nm, respectively.

In some embodiments, the diffusing the n-type dopant into the III-V semiconductor substrate and the diffusing the co-dopant into the III-V semiconductor substrate result in a doped III-V semiconductor substrate, where the doped portion of the semiconductor substrate has an n-type dopant concentration that is 5×10¹⁸ atoms/cm³ to 2×10²¹ atoms/cm³ (including any and all ranges and subranges therein) over a depth of less than or equal to 12 nm (e.g., 12 nm, 11 nm, 10 nm, 9 nm, 8 nm, 7 nm, 6 nm, 5 nm, 4 nm, etc.) from the surface of the III-V semiconductor substrate, and is less than 5×10¹⁸ atoms/cm³ beyond said less than or equal to 12 nm from the surface of the III-V semiconductor substrate.

In another aspect, the invention provides a semiconductor structure. The semiconductor structure may be made according to the first aspect of the invention. The semiconductor structure comprises a region of III-V semiconductor substrate having a crystalline lattice comprising atoms of one or more group III elements (e.g., Ga, In) and one or more group V elements (e.g., As), wherein a plurality of group V atom sites (e.g., As sites) and/or a plurality of group V interstitial sites (e.g., As interstitial sites) in said lattice are occupied by a co-dopant selected from nitrogen (N) and phosphorus (P). The said region of III-V semiconductor substrate includes a surface of the III-V semiconductor substrate. An n-type dopant selected from sulfur (S), selenium (Se), and tellurium (Te) is present in said region of III-V semiconductor substrate at a concentration greater than or equal to 5×10¹⁸ atoms/cm³ over a depth of less than or equal to 12 nm (e.g., 12 nm, 11 nm, 10 nm, 9 nm, 8 nm, 7 nm, 6 nm, 5 nm, 4 nm, etc.) from the surface of the III-V semiconductor substrate, and at a concentration less than 5×10¹⁸ atoms/cm³ beyond 12 nm from the surface of the III-V semiconductor substrate.

In some embodiments, the n-type dopant concentration in the said region of III-V semiconductor substrate is greater than or equal to 5×10¹⁸ atoms/cm³ over a depth of 12 nm, 11 nm, 10 nm, 9 nm, 8 nm, 7 nm, 6 nm, 5 nm, or 4 nm, and the n-dopant concentration is less than 5×10¹⁸ atoms/cm³ beyond a depth of 12 nm, 11 nm, 10 nm, 9 nm, 8 nm, 7 nm, 6 nm, 5 nm, or 4 nm, respectively.

In some embodiments, the III-V semiconductor substrate (e.g., InGaAs), has a doped portion that has an n-type dopant concentration that is 5×10¹⁸ atoms/cm³ to 2×10²¹ atoms/cm³ (including any and all ranges and subranges therein) over a depth of less than or equal to 12 nm (e.g., 12 nm, 11 nm, 10 nm, 9 nm, 8 nm, 7 nm, 6 nm, 5 nm, 4 nm, etc.) from the surface of the III-V semiconductor substrate, and is less than 5×10¹⁸ atoms/cm³ beyond said less than or equal to 12 nm from the surface of the III-V semiconductor substrate.

In another aspect, the invention provides a semiconductor device comprising the inventive semiconductor structure, which may be made according to the inventive method.

In another aspect, the invention provides an electronic device comprising the inventive semiconductor structure, which may be made according to the inventive method.

A non-limiting embodiment of the invention is described in the example below.

### EXAMPLE PREPARATION

### Example 1

A substrate having an InP lower layer, a 40 nm InAlAs middle layer, and an InGaAs semiconductor substrate top layer was provided. The InGaAs surface cleaned with dilute HCl (HCl:H₂O—1:10). Sulfur (n-type dopant) and phosphorus (co-dopant) were introduced to the InGaAs surface via monolayer deposition using a solution comprising phosphorus pentasulfide (P₂S₅), thereby forming directly on the InGaAs substrate a layer comprising the n-type dopant (sulfur) and the co-dopant (phosphorus). In particular, ammonium sulfide solution (NH₄)₂S was heated to 35° C. (degrees Celsius). Phosphorus pentasulfide (P₂S₅) was added to the solution until it saturated in the solution (i.e. (NH₄)₂S). The solution was further diluted to a ratio of 1:1000 with H₂O before processing. A 20 nm silicon oxide layer was then deposited on the InGaAs substrate. An activation anneal was performed at 700° C. for 30 seconds. Next, a 20 nm silicon oxide strip with dilute HF (HF:H₂O-1:100) was performed.

### Counterexample 1a

An example was prepared according to inventive Example 1 above, except that no co-dopant was used. A substrate having an InP lower layer, a 40 nm InAlAs middle layer, and an InGaAs semiconductor substrate top layer was provided. The InGaAs surface cleaned with dilute HCl (HCl:H₂O-1:10). Sulfur (n-type dopant) was introduced to the InGaAs surface via monolayer deposition using a sulfur-comprising solution ((NH₄)₂S+S in dilution with H₂O in the ratio of 1:1000 at 35° C.), thereby forming directly on the InGaAs substrate a layer comprising the n-type dopant (sulfur). A 20 nm silicon oxide layer was then deposited on the InGaAs substrate. An activation anneal was performed at 700° C. for 30 seconds. Next, a 20 nm silicon oxide strip with dilute HF (HF:H₂O-1:100) was performed.

### Results

Element concentration as a function of depth was determined for Example 1 and Counterexample 1A using secondary ion mass spectrometry (SIMS), a technique well-known in the art.

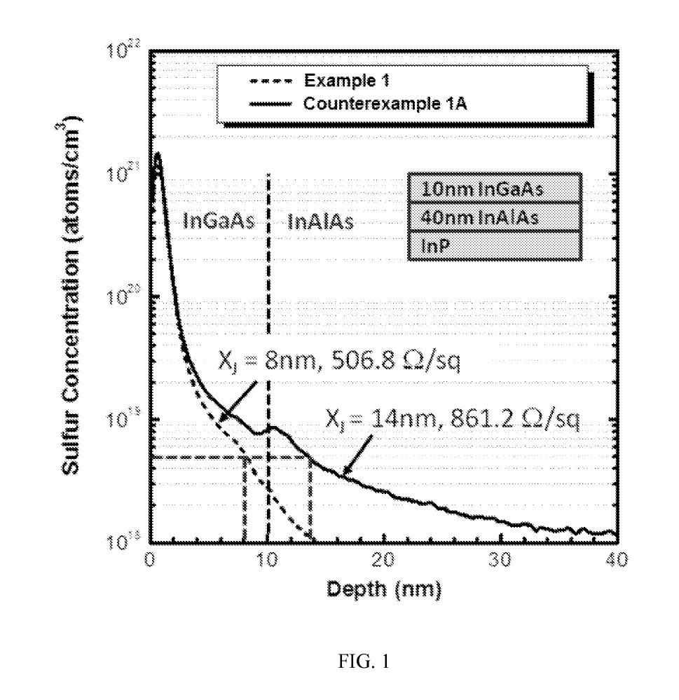

FIG. 1 is a graph showing n-type dopant (sulfur) concentration as a function of substrate depth for Example 1 and Counterexample 1A. The surface of the III-V (InGaAs) substrate is represented by the y-axis (0 nm). As shown, in the absence of the co-dopant (which, for Example 1, was phosphorus), the junction depth (at 5×10¹⁸ atoms/cm³) for Counterexample 1A was 14 nm. On the other hand, presence of the co-dopant in inventive Example 1 advantageously resulted in a much shallower junction (8 nm). Thus, the inventive co-doping process effectively achieves a much shallower junction. Further, as shown in FIG. 1, n-type dopant diffusion into the bulk it severely inhibited in the inventive embodiment, whereas, in Counterexample 1, significant diffusion occurred.

As demonstrated above, the inventive method provides an inventive semiconductor structure having limited diffusion of n-type dopant, thereby enabling ultra-shallow junction (USJ) formation. The invention also encompasses various other non USJ-related doping processes and semiconductor structures where limited dopant diffusion is desired.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), “contain” (and any form contain, such as “contains” and “containing”), and any other grammatical variant thereof, are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

As used herein, the terms “comprising,” “has,” “including,” “containing,” and other grammatical variants thereof encompass the terms “consisting of” and “consisting essentially of.”

The phrase “consisting essentially of” or grammatical variants thereof when used herein are to be taken as specifying the stated features, integers, steps or components but do not preclude the addition of one or more additional features, integers, steps, components or groups thereof but only if the additional features, integers, steps, components or groups thereof do not materially alter the basic and novel characteristics of the claimed composition, device or method.

All publications cited in this specification are herein incorporated by reference as if each individual publication were specifically and individually indicated to be incorporated by reference herein as though fully set forth.

Subject matter incorporated by reference is not considered to be an alternative to any claim limitations, unless otherwise explicitly indicated.

Where one or more ranges are referred to throughout this specification, each range is intended to be a shorthand format for presenting information, where the range is understood to encompass each discrete point within the range as if the same were fully set forth herein.

While several aspects and embodiments of the present invention have been described and depicted herein, alternative aspects and embodiments may be affected by those skilled in the art to accomplish the same objectives. Accordingly, this disclosure and the appended claims are intended to cover all such further and alternative aspects and embodiments as fall within the true spirit and scope of the invention.

1. A method of fabricating a semiconductor structure, said method comprising:
providing a III-V semiconductor substrate selected from InGaAs and InAs;
introducing an n-type dopant directly onto a surface of the III-V semiconductor substrate, wherein said n-type dopant is selected from sulfur (S), selenium (Se), and tellurium (Te);
introducing a co-dopant directly onto a surface of the III-V semiconductor substrate, wherein said co-dopant is selected from nitrogen (N) and phosphorus (P);
diffusing the n-type dopant into the III-V semiconductor substrate; and
diffusing the co-dopant into the III-V semiconductor substrate;
thereby forming an n-doped III-V semiconductor substrate containing the n-type dopant and the co-dopant.

2. The method according to claim 1, wherein the III-V semiconductor substrate is InGaAs.

3. The method according to claim 1, wherein the III-V semiconductor substrate is InAs.

4. The method according to claim 2, wherein the co-dopant is phosphorus and the n-type dopant is sulfur.

5. The method according to claim 1, wherein the co-dopant is phosphorus.

6. The method according to claim 1, wherein the n-type dopant is sulfur.

7. The method according to claim 6, wherein the co-dopant is phosphorus.

8. The method according to claim 7, wherein the III-V semiconductor substrate is InAs.

9. The method according to claim 1, wherein:
said introducing an n-type dopant directly onto a surface of the III-V semiconductor substrate, and said introducing a co-dopant directly onto a surface of the III-V semiconductor substrate are accomplished by:
(a) molecular beam epitaxy (MBE);
(b) metal organic chemical vapor deposition (MOCVD);
(c) monolayer deposition (MLD);
(d) plasma deposition; or
(e) vapor phase deposition.

10. The method according to claim 1, wherein:
said introducing an n-type dopant directly onto a surface of the III-V semiconductor substrate, and said introducing a co-dopant directly onto a surface of the III-V semiconductor substrate are accomplished by monolayer deposition; and
said diffusing the n-type dopant and said diffusing the co-dopant are accomplished by annealing.

11. The method according to claim 10, wherein said monolayer deposition comprises contacting the III-V semiconductor surface with a solution comprising the n-type dopant and the co-dopant, thereby forming a layer comprising the n-type dopant and the co-dopant on the III-V semiconductor surface.

12. The method according to claim 11, wherein the III-V semiconductor substrate is InGaAs, the n-type dopant is sulfur (S), and the co-dopant is phosphorus (P).

13. The method according to claim 12, wherein the solution comprises tetraphosphorus decasulfide.

14. The method according to claim 1, wherein said diffusing the n-type dopant and said diffusing the co-dopant are accomplished by annealing, and wherein, following said annealing, the concentration of the n-type dopant in one or more portions of the III-V semiconductor substrate is greater than or equal to 5×10¹⁸ atoms/cm³ over a depth of less than or equal to 12 nm from the surface of the III-V semiconductor substrate, and is less than 5×10¹⁸ atoms/cm³ beyond 12 nm from the surface of the semiconductor substrate.

15. The method according to claim 14, wherein, following said annealing, the concentration of the n-type dopant in one or more portions of the III-V semiconductor substrate is 5×10¹⁸ atoms/cm³ to 2×10²¹ atoms/cm³ over a depth of less than or equal to 8 nm from the surface of the III-V semiconductor substrate, and is less than 5×10¹⁸ atoms/cm³ beyond 8 nm from the surface of the III-V semiconductor substrate.

16. A semiconductor device comprising a semiconductor structure made according to the method of claim 1.

17. A semiconductor structure comprising a region of III-V semiconductor substrate selected from InGaAs and InAs, having a crystalline lattice comprising atoms of one or more group III elements and one or more group V elements,
wherein a plurality of group V atom sites and/or a plurality of group V interstitial sites in said lattice are occupied by a co-dopant selected from nitrogen (N) and phosphorus (P),
wherein said region of III-V semiconductor substrate includes a surface of the III-V semiconductor substrate, and
wherein an n-type dopant selected from sulfur (S), selenium (Se), and tellurium (Te) is present in said region of III-V semiconductor substrate at a concentration greater than or equal to 5×10¹⁸ atoms/cm³ over a depth of less than or equal to 12 nm from the surface of the III-V semiconductor substrate, and at a concentration less than 5×10¹⁸ atoms/cm³ beyond 12 nm from the surface of the III-V semiconductor substrate.

18. The semiconductor structure according to claim 17, wherein the III-V semiconductor substrate is InGaAs, the n-type dopant is sulfur (S), and the co-dopant is phosphorus (P).

19. The semiconductor structure according to claim 18, wherein the sulfur is present in said region of III-V semiconductor substrate at a concentration of 5×10¹⁸ atoms/cm³ to 2×10²¹ atoms/cm³ over a depth of less than or equal to 8 nm from the surface of the III-V semiconductor substrate, and at a concentration less than 5×10¹⁸ atoms/cm³ beyond 8 nm from the surface of the III-V semiconductor substrate.

20. An electronic device comprising the semiconductor structure according to claim 17.
